(19) United States
(12) Patent Application Publication
(10) Pub. No.: US 2025/0035672 A1
(43) Pub. Date: Jan. 30, 2025

(54) MEASUREMENT APPLICATION CONTROL DEVICE, NETWORK COMMUNICATION DEVICE, AND METHOD

(71) Applicant: Rohde & Schwarz GmbH & Co. KG, München (DE)

(72) Inventors: Andreas GEROLD, Kolbermoor (DE); Björn SCHMID, München (DE)

(21) Appl. No.: 18/361,474

(22) Filed: Jul. 28, 2023

(51) Int. Cl. G01R 1/067; G01R 13/02

(52) U.S. Cl. CPC G01R 1/06788; G01R 13/029

(57) ABSTRACT

The present disclosure provides a measurement application control device comprising a communication interface, a unified communication controller configured to establish at least one communication connection to a unified network communication partner over the communication interface, and a measurement application configured to establish at least one application data connection according to a specific communication pattern to at least one application communication partner via the unified communication controller, and to exchange measurement application data with the at least one application communication partner via the at least one application data connection, wherein the unified communication controller is configured to enclose the at least one application data connection in the at least one communication connection for provision of the measurement application data to the respective application communication partner by the unified network communication partner. Further, the present disclosure relates to a respective network communication device, and a respective method.

### TECHNICAL FIELD

The disclosure relates to a measurement application control device. Further, the present disclosure relates to a respective network communication device, and a respective method.

### BACKGROUND

Although applicable to any type of measurement application device, the present disclosure will mainly be described in conjunction with network-connected measurement devices that operate in communication networks.

Modern measurement application devices usually not only comprise measurement and user interfaces. Instead, modern measurement application devices also comprise network interface for communicating with other network-enabled devices.

Integrating such measurement application devices into existing networks may cause additional effort or may even be impossible, when security measures like closed firewall ports, and the like, are present in the respective network.

Accordingly, there is a need for improving network communication of measurement application devices.

### SUMMARY

The above stated problem is solved by the features of the independent claims. It is understood, that independent claims of a claim category may be formed in analogy to the dependent claims of another claim category.

Accordingly, it is provided:

A measurement application control device comprising a communication interface, a processor configured to execute instructions that cause the processor to perform the functions of a unified communication library configured to establish at least one communication connection to a unified network communication partner over the communication interface, and a measurement application configured to establish at least one application data connection according to a specific communication pattern to at least one application communication partner via the unified communication library, and to exchange measurement application data with the at least one application communication partner via the at least one application data connection, wherein the unified communication library is further configured to enclose the at least one application data connection in the at least one communication connection for provision of the measurement application data to the respective application communication partner by the unified network communication partner, and wherein the unified communication library comprises a pattern-specific interface for at least one communication pattern, and wherein the measurement application is configured to establish the at least one application data connection via the pattern-specific interface.

Further, it is provided:

A measurement application control device comprising a communication interface, a unified communication controller configured to establish at least one communication connection to a unified network communication partner over the communication interface, and a measurement application configured to establish at least one application data connection according to a specific communication pattern to at least one application communication partner via the unified communication controller, and to exchange measurement application data with the at least one application communication partner via the at least one application data connection, wherein the unified communication controller is configured to enclose the at least one application data connection in the at least one communication connection for provision of the measurement application data to the respective application communication partner by the unified network communication partner.

Further, it is provided:

A network communication device comprising a communication interface, and a server-side unified communication controller configured to establish at least one communication connection with a measurement application control device over the communication interface, wherein the server-side unified communication controller is configured to receive data for at least one application data connection via the at least one communication connection, and to unpack the data, and to forward the data to a respective application communication partner.

Further, it is provided:

A measurement application control method comprising establishing at least one communication connection to a unified network communication partner, establishing at least one application data connection according to a specific communication pattern to at least one application communication partner, exchanging measurement application data of a measurement application with the at least one application communication partner via the at least one application data connection, and enclosing the at least one application data connection in the at least one communication connection for provision of the measurement application data to the respective application communication partner.

The present disclosure is based on the finding that establishing a large number of network connections from one communication partner to another communication partner may be difficult under certain circumstances.

For example, the number of WebSockets that a single application in a web browser may establish to a single server is usually limited. For remote control of modern measurement application devices, like oscilloscopes or vector network analyzers, a remote-control application, for example a browser based one-page application, has to consider such limitations.

In modern measurement application environments, the remote-control application may be coupled to the respective measurement application devices indirectly via a plurality of data networks and communication systems, for example, local data networks, the internet, cloud-based servers, switches, hubs, and routers.

In such data networks, many limitations will be implemented. For example, specific ports may be blocked by firewalls, and the number of connections from one host to another may be limited.

In many installations, the IT security rules may not allow opening the required ports for specific communication patterns. Especially, for usage with multiple different communication patterns, the blocking of ports may, consequently, be a limiting factor.

To overcome such shortcomings, remote-control applications usually open one ore only a few network connections directly to the respective measurement application device that is to be controlled, e.g., a single WebSocket connection. The multiplexing of different types of data is then managed internally by the application.

Such an arrangement, however, does not allow for an easy usage of a plurality of different communication patterns in the remote-control application. Nevertheless, using different communication patterns at the same time may be important for specific use cases of remote-control applications for measurement application devices.

If the multiplexing of different types of data is managed internally by the remote-control application, new communication patterns may not easily be added to the remote-control application, since the internals of the remote-control application need to be adapted to the new communication patterns.

With a measurement application control device, a network communication device, or a measurement application control method according to the present disclosure, such shortcomings are easily overcome.

It is understood, that a measurement application control device according to the present disclosure may be implemented in any type of measurement application device that actively acquires or generates signals in the respective measurement application. A measurement application control device according to the present disclosure may also comprise or be provided in any supporting device or software that may be used in the measurement application to e.g., control or monitor other measurement application devices.

In general, a measurement application device according to the present disclosure may comprise any device that may be used in a measurement application to acquire an input signal or to generate an output signal, or to perform additional or supporting functions in a measurement application. A measurement application device may also comprise or be implemented as application or applications, also called measurement application or measurement applications, that may be executed on a computer device and that may communicate with other measurement application devices in order to perform a measurement task. A measurement application, also called measurement setup, may e.g., comprise at least one or multiple different measurement application devices for performing electric, magnetic, or electromagnetic measurements, especially on single devices under test. Such electric, magnetic, or electromagnetic measurements may be performed in a measurement laboratory or in a production facility in the respective production line. A measurement application or measurement setup may serve to qualify the single devices under test i.e., to determine the proper electrical operation of the respective devices under test.

Measurement application devices to this end may comprise at least one signal acquisition section for acquiring electric, magnetic, or electromagnetic signals to be measured from a device under test, or at least one signal generation section for generating electric, magnetic, or electromagnetic signals that may be provided to the device under test. Such a signal acquisition section may comprise, but is not limited to, a front-end for acquiring, filtering, and attenuating or amplifying electrical signals. The signal generation section may comprise, but is not limited to, respective signal generators, amplifiers, and filters.

Further, when acquiring signals, measurement application devices may comprise a signal processing section that may process the acquired signals. Processing may comprise converting the acquired signals from analog to digital signals, and any other type of digital signal processing, for example, converting signals from the time-domain into the frequency-domain.

The measurement application devices may also comprise a user interface to display the acquired signals to a user and allow a user to control the measurement application devices. Of course, a housing may be provided that comprises the elements of the measurement application device. It is understood, that further elements, like power supply circuitry, and communication interfaces may be provided.

A measurement application device may be a stand-alone device that may be operated without any further element in a measurement application to perform tests on a device under test. Of course, communication capabilities may also be provided for the measurement application device to interact with other measurement application devices.

A measurement application device may comprise, for example, a signal acquisition device e.g., an oscilloscope, especially a digital oscilloscope, a spectrum analyzer, or a vector network analyzer. Such a measurement application device may also comprise a signal generation device e.g., a signal generator, especially an arbitrary signal generator, also called arbitrary waveform generator, or a vector signal generator. Further possible measurement application devices comprise devices like calibration standards, or measurement probe tips.

Of course, at least some of the possible functions, like signal acquisition and signal generation, may be combined in a single measurement application device.

In embodiments, the measurement application device may comprise pure data acquisition devices that are capable of acquiring an input signal and of providing the acquired input signal as digital input signal to a respective data storage or application server. Such pure data acquisition devices not necessarily comprise a user interface or display. Instead, such pure data acquisition devices may be controlled remotely e.g., via a respective data interface, like a network interface or a USB interface. The same applies to pure signal generation devices that may generate an output signal without comprising any user interface or configuration input elements. Instead, such signal generation devices may be operated remotely via a data connection.

In order to allow measurement application devices to easily communicate with each other or with a measurement application control device according to the present disclosure, the measurement application control device of the present disclosure comprises the unified communication controller. The unified communication controller may be seen as central communication aggregator that serves in the measurement application control device to allow communication via any required communication pattern for any number of application data connections, while at the same time bundling all application data connections into only one communication connection, or at least a controlled number of communication connections that is supported in the respective operating environment. The term “communication connection” in the context of the present invention is to be understood as an actual connection that allows transmitting data between a sender and a receiver. In a networking environment, such a connection may be a network connection. Other possible types of connections will be described in more detail below.

The unified communication controller may, in embodiments, be provided as a unified communication library. Such a library may be included in the respective application.

In an exemplary embodiment, the measurement application control device may be a computer that executes a web-browser application, wherein an HTML-based and JavaScript-based application is loaded by the web-browser application. The application loaded by the web-browser application may e.g., be a remote-control application for an oscilloscope that may be loaded from a cloud-server.

In order to control the oscilloscope, the remote-control application may show a plurality of input elements and output elements to a user. Each of the output elements will require data from the oscilloscope to be displayed to the user, while the input elements will require data received from a user to be transmitted to the oscilloscope.

According to the present disclosure, the remote-control application is provided with the unified communication controller, e.g., in the form of a unified communication library that may be loaded with the remote-control application.

The unified communication controller will allow each element of the remote-control application to establish any number of application data connections to the oscilloscope using any required communication pattern, especially using different communication patterns as required for each application data connection.

The term “application data connection” in the context of the present disclosure is to be understood as a virtual connection between two nodes. Such an application data connection may be established and may be based on any type of communication pattern independently of any underlying communication connection, networking technology, and data connections. The application data connection may e.g., be requested or established by the respective input element or output element via the unified communication controller. The unified communication controller will then establish the application data connection for the respective element.

The unified communication controller encloses all application data connections into a respective communication connection, or a number of communication connections that is supported in the respective environment. The data packets of the one or more communication connections are provided from the unified communication controller to a respective unified network communication partner. The unified network communication partner may, in embodiments, be implemented by a network communication device according to the present disclosure, hardware- or software-based.

The unified communication library in the measurement application control device may comprise a pattern-specific interface for at least one communication pattern, especially for a plurality or all of the communication patterns that are used by the measurement application. In such embodiments, the measurement application will establish the application data connection via the pattern-specific interface.

In exemplary embodiments where the measurement application is provided as a web-based application, the unified communication library may, for example, replace the standard functions provided by the web browser. The unified communication library may e.g., replace or overwrite the standard requests object for providing a request-response-pattern-based application data connection. This allows using a plurality of components for the web application that rely on the requests object, and still providing the benefits of the unified communication library.

It is understood that the requests object is just exemplarily presented, and that any other adequate object may be replaced or overwritten for providing communication via other communication patterns. New objects or interfaces that are not present, and can therefore not be replaced or overwritten, may also be provided.

In general, the components not necessarily need to use the requests object. In fact, each component may use any of the available communication patterns.

Using the solution of the present disclosure allows independently developing or maintaining the single components that are used in the measurement application. Each one of the components may establish any application data connection it may require, without having to respect any limitations of the respective operating environment. This greatly simplifies development and maintenance of the single components.

While above, a web-based application was described as remote-control measurement application control device, the measurement application control device according to the present disclosure may also be a hardware device, for example an oscilloscope, or a signal generator, that communicates with other measurement application devices.

In exemplary embodiments, the unified communication controller may be provided as a program library e.g., a C++ library or a library written in any other programming language that may be loaded or dynamically linked by applications that are executed in the respective measurement application control device. In such an embodiment, the application may directly access or use functions of the library.

Of course, the measurement application control device may comprise a respective processor that executes instructions that cause the processor to perform the function of the unified communication controller, and the measurement application.

Generally, the processor, the unified communication library, the unified communication controller, and the measurement application may comprise or may be provided in or as part of at least one of a dedicated processing element e.g., a processing unit, a microcontroller, a field programmable gate array, FPGA, a complex programmable logic device, CPLD, an application specific integrated circuit, ASIC, or the like. A respective program or configuration may be provided to implement the required functionality. The processor, the unified communication library, the unified communication controller, and the measurement application may at least in part also be provided as a computer program product comprising computer readable instructions that may be executed by a processing element. In a further embodiment, the processor, the unified communication library, the unified communication controller, and the measurement application may be provided as addition or additional function or method to the firmware or operating system of a processing element that is already present in the respective application as respective computer readable instructions. Such computer readable instructions may be stored in a memory that is coupled to or integrated into the processing element. The processing element may load the computer readable instructions from the memory and execute them.

In addition, it is understood, that any required supporting or additional hardware may be provided like e.g., a power supply circuitry and clock generation circuitry.

Summing up, with the measurement application control device according to the present disclosure, a plurality of application data connections may be established without the need to limit the number and type of connections according to the respective environment. Only the number and type of communication connections needs to be adapted to the operating environment. However, the limited number of communication connections does not limit the number of possible application data connections.

On the receiving side of the communication connection, the network communication device according to the present disclosure, also called the unified network communication partner, will receive the data transmitted via the one or more communication connections.

The unified network communication partner will then unpack or extract the data of each one of the application data connections from the data received via the one or more communication connections, and provide the data of the respective application data connections to their destination.

To this end, the unified network communication partner or network communication device comprises a communication interface for performing the data transmission. The unified network communication partner or network communication device further comprises a server-side unified communication controller that receives the data for the single application data connections enclosed in the communication connection.

The term “enclosed” in this regard may exemplarily refer to the data of the single application data connections being packetized or partitioned, each packet or partition being provided with an identifier, that allows identifying data that belongs together, and the start or end of a data stream. The packetized or partitioned data is then embedded in the communication connection e.g., in data packets of the communication connection. Therefore, the single communication patterns are mapped or multiplexed into the one or more communication connections.

As indicated, a single communication connection or multiple communication connections may be used, thereby bundling the transport capacity of multiple communication connections.

Further, application data connections may be established between only two devices, or between ore than two devices. For example, a emote-control application may establish application data connections to a single one or to multiple measurement application devices.

In the context of the present disclosure, the term “communication interface” is meant to encompass or comprise any kind of wired and wireless communication interfaces, like for example a network communication interface, especially an Ethernet, wireless LAN or WIFI interface, a USB interface, a Bluetooth interface, an NFC interface, a visible or non-visible light-based interface, especially an infrared interface.

The present disclosure provides communication connections that enclose application data connections. It is understood, that the terms communication connection and application data connection are not intended to limit the communication to any specific technology or to specific details, like a communication layer of the OSI model. While a communication connection may be provided on a lower layer than the application data connections, the communication connections and the application data connections may also be provided on the same layer, or the application data connections may be on a lower layer than the communication connections. This flexibility allows transmitting any type of data in the communication connections, while allowing to implement the communication connections in any communication environment.

The communication connections, and the application data connections do not need to be of the same type or technology. If the measurement application control device and the network communication device are provided in a single device, the application data connections may e.g., be network connections, while the communication connection may use a shared memory approach to exchange data.

It is noted that while the communication between measurement application control devices according to the present disclosure may comprise data for remote-control of a measurement application device, the data is not limited to remote-control data. In embodiments, any combination of remote-control data, measurement data, and service data may be exchanged.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to the device can be combined in all variations with each other and the disclosure of the description is not limited to the claim dependencies as specified in the claim set. Further, the features of the other independent claims may be combined with any of the features of the dependent claims relating to the device in all variations, wherein respective method steps may implement the functions of the respective apparatus elements.

In an embodiment, which can be combined with all other embodiments of the measurement application control device mentioned above or below, the unified communication controller may comprise a pattern-specific interface for at least one communication pattern, wherein the measurement application may be configured to establish the at least one application data connection via the pattern-specific interface.

The term “pattern-specific interface” refers to the unified communication controller or unified communication library comprising an interface for every communication pattern that is directly supported by the unified communication controller.

The term “interface” in this regard refers to any type of adequate interface. If the unified communication controller is provided as a computer program product comprising respective instructions, the interface may comprise an API endpoint, a callable function, or any other intra-application interface that allows the measurement application to use the respective interface.

In the case that the unified communication controller is provided as a library, especially a JavaScript library, and the measurement application is a JavaScript-based application, the unified communication controller may overwrite existing standard interfaces, like the request object or interface, as described above. Of course, the unified communication controller in such embodiments may also overwrite other interfaces or functions for other communication patterns. Examples of other interfaces that may be overwritten comprise, but are not limited to, the standard WebSockets interface, or the MQTT interface provided by the MQTT.js library.

Of course, the unified communication controller or unified communication library may replace the original interface. In other embodiments, the unified communication controller or unified communication library may in the background access the original interface for the respective communication pattern. The unified communication controller or unified communication library will in such embodiments serve as an intermediary layer that may perform any required function to include the data of the respective application data connection into the respective communication connection.

In another embodiment, which can be combined with all other embodiments of the measurement application control device mentioned above or below, the communication pattern comprises at least one of a request-response communication pattern, a remote procedure call communication pattern, a publish-subscribe communication pattern, and an event-channel communication pattern.

The request-response, also called request-reply, communication pattern comprises a first node actively sending a request to another node, while the other node provides a response to the respective first node. The request-response communication pattern is a message exchange pattern in which usually a requestor sends a request message to a replier system, which receives and processes the request, and returns a response message in response to the request after finishing processing.

The remote procedure call communication pattern may be implemented as a special form of a request-response communication pattern. With the remote procedure call communication pattern, a computer program causes a procedure to execute e.g., in a different computer, like a server on a network. The procedure call may be written as if it were a normal (local) procedure call, without the programmer explicitly writing the details for the remote interaction.

In the publish-subscribe communication pattern senders of messages, also called publishers, do not send the messages directly to the receivers, also called subscribers. Instead, the publishers usually categorize the published messages into classes or topics. The publishers do not need to have any knowledge of the subscribers, if any, that may subscribe to the respective category or topic. The subscribers express their interest in one or more classes or topics by subscribing the classes or topics, and receive all messages in that categories or topics without needing explicit knowledge about the publishers. A so-called broker or message-broker may manage the subscriptions and distribution of the single messages.

The event-channel communication pattern is based on event channels that bundle information about events that occurred. Interested receivers may subscribe to the respective channel and will receive all the events of that channel. The receivers may then act accordingly. The event-channel communication pattern may be implemented as a special type of publish-subscribe communication pattern.

Providing the ability to use different communication patterns, allows implementing the teaching of the present disclosure in a plurality of different situations.

In an exemplary embodiment, a user may use a web-browser to control a measurement application device, like an oscilloscope. The web-browser may load a remote-control application. This remote-control application may be an implementation of the measurement application control device according to the present disclosure, and serve for controlling one or more other measurement application devices that may e.g., be measurement devices or signal generation devices.

The remote-control application may comprise a plurality of user interface elements or UI elements, wherein each one of the UI elements may display different data from the measurement application device that is controlled, or receive different user input for transmission to the measurement application device that is controlled.

Each one of the UI elements may, therefore, open one or more application data connections to the measurement application device that is controlled.

An exemplary UI element may comprise the display of the value of a rotary knob on the measurement application device that is controlled. When loading the UI element, the remote-control application may load the initial value of the UI element via the request-response communication pattern. At the same time, the remote-control application may subscribe to the value of the rotary know that may be published by the measurement application device that is controlled via a publish-subscribe communication pattern. If a user turns the rotary knob on the actual hardware measurement application device, the UI element will receive the updated value and will immediately show the new value.

Without the present disclosure, with an increasing number of UI elements, an increasing number of communication connections needs to be established. However, with the present disclosure, the single application data connections will be enclosed in only one or a small number of communication connections. At the same time, the developer of the remote-control application does not need to worry about the number of UI elements and the required number of application data connections.

In a further embodiment, which can be combined with all other embodiments of the measurement application control device mentioned above or below, the at least one communication connection may comprise at least one of a network connection, a TCP/IP connection, a WebSocket connection, a shared memory connection, and an API function call.

As explained above, the at least one communication connection serves to include or enclose a plurality of application data connections. Therefore, in embodiments, the communication connections may be provided on a lower layer than the application data connections.

Generally, the communication connections may be provided as network connections, for example, as TCP/IP connections, or as WebSocket connections. Especially, the use of WebSocket connections allows easily establishing the communication connections with readily available libraries on both ends of such a connection. On the other hand, the use of pure TCP/IP connections may provide more liberty and flexibility to the developer.

In cases, where the communication connection is not established over a network, but within a single device, the communication connection may also be established as a shared memory connection or shared memory access, or as an API function call to APIs or functions provided within the respective device.

In other embodiments, the at least one communication connection may also be provided based on any of the above-mentioned communication patterns.

In another embodiment, which can be combined with all other embodiments of the measurement application control device mentioned above or below, the unified communication controller may be configured to prioritize the at least one application data connection, and transmit data of the at least one application data connection according to the prioritization.

Especially with multiple application data connections, specific ones of the application data connections may relate to data that is more important, or that should be updated quicker than data of other application data connections.

The priority of the single application data connections may be defined based on different criteria. In embodiments, the priority may depend on the communication pattern a specific application data connection uses. In other embodiments, the priority may be user set. If the final consumer of the data is a UI element, the priority may also depend on the type of UI element. For example, diagram data may be prioritized over data for a rotary knob, or a switch.

By prioritizing the data or the single application data connections, it may be made sure that the most important data is transmitted first.

In an embodiment, which can be combined with all other embodiments of the measurement application control device mentioned above or below, the unified communication controller may be configured to receive data for the at least one application data connection via the at least one communication connection, and forward the data to the measurement application.

The server-side unified communication controller may further be configured to receive data for the at least one application data connection from the respective application communication partner, and transmit the data of the at least one application data connection enclosed in the at least one communication connection to the measurement application control device.

It is understood, that the application data connections are not necessarily provided as one-way data connections. Instead, the unified communication controller or unified communication library may also receive data via the application data connection, and provide the data to the measurement application.

As explained above, in the measurement application, the data may e.g., be used to update a user interface that serves for remotely controlling another measurement application device.

In another embodiment, which can be combined with all other embodiments of the measurement application control device mentioned above or below, the measurement application control device may further comprise a pattern translator configured to translate data according to a predetermined communication pattern into data according to another communication pattern, wherein the unified communication controller is configured to access the pattern translator to translate data according to a predetermined communication pattern into data according to another communication pattern prior to transmission of the data in the at least one communication connection.

The pattern translator or pattern translator library serves for providing a specific communication pattern interface to the measurement application. At the same time, the pattern translator or pattern translator library allows handling the data received from the measurement application or provided to the measurement application in any other adequate format or communication pattern.

For example, a measurement application may try to establish a publish-subscribe application data connection, e.g., an MQTT application data connection. With the pattern translator or pattern translator library, the measurement application may be provided with such a publish-subscribe application data connection, while the connection is established to the respective node via any other communication pattern, e.g., a request-response pattern.

The pattern translator or pattern translator library, therefore, allows flexibly coupling measurement applications to nodes, even if they use different communication patterns.

In an embodiment, which can be combined with all other embodiments of the measurement application control device mentioned above or below, in the measurement application control device the unified communication controller may be configured to retrieve communication details for the unified network communication partner from a network-connected server, and to establish the communication connection to the unified network communication partner according to the communication details, wherein the communication details comprise at least a TCP/IP network address and a TCP/IP port.

In the network communication device, the server-side unified communication library may be configured to provide communication details about the application communication partner to the measurement application control device for establishing the communication connection to the unified network communication partner according to the communication details, wherein the communication details comprise at least a TCP/IP network address and a TCP/IP port.

The network-connected server may provide the communication details to the unified communication controller, in order to perform a firewall or NAT hole punching. Of course, the network-connected server may provide according information to the other end of the communication e.g., a measurement application device.

The unified communication controller, and the measurement application device may with the help of the network-connected server try to establish a direct connection, and communicate with each other directly, without the need to provide an intermediary server that bridges both nodes.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of a measurement application control device according to the present disclosure;

FIG. 2 shows a block diagram of another embodiment of a measurement application control device according to the present disclosure;

FIG. 3 shows a block diagram of another embodiment of a measurement application control device according to the present disclosure;

FIG. 4 shows a block diagram of another embodiment of a measurement application control device according to the present disclosure;

FIG. 5 shows a block diagram of another embodiment of a measurement application control device according to the present disclosure;

FIG. 6 shows a block diagram of an embodiment of a network communication device according to the present disclosure;

FIG. 7 shows a block diagram of a measurement application with an embodiment of a measurement application control device according to the present disclosure;

FIG. 8 shows a block diagram of a measurement application with another embodiment of a measurement application control device according to the present disclosure;

FIG. 9 shows a flow diagram of an embodiment of a measurement application control method according to the present disclosure;

FIG. 10 shows a flow diagram of another embodiment of a measurement application control method according to the present disclosure;

FIG. 11 shows a flow diagram of another embodiment of a measurement application control method according to the present disclosure;

FIG. 12 shows a flow diagram of another embodiment of a measurement application control method according to the present disclosure;

FIG. 13 shows a flow diagram of another embodiment of a measurement application control method according to the present disclosure;

FIG. 14 shows a block diagram of an oscilloscope that may be used with an embodiment of a measurement application control device according to the present disclosure; and

FIG. 15 shows a block diagram of an oscilloscope that may be used with an embodiment of a measurement application control device according to the present disclosure.

In the figures like reference signs denote like elements unless stated otherwise.

### DETAILED DESCRIPTION OF THE DRAWINGS

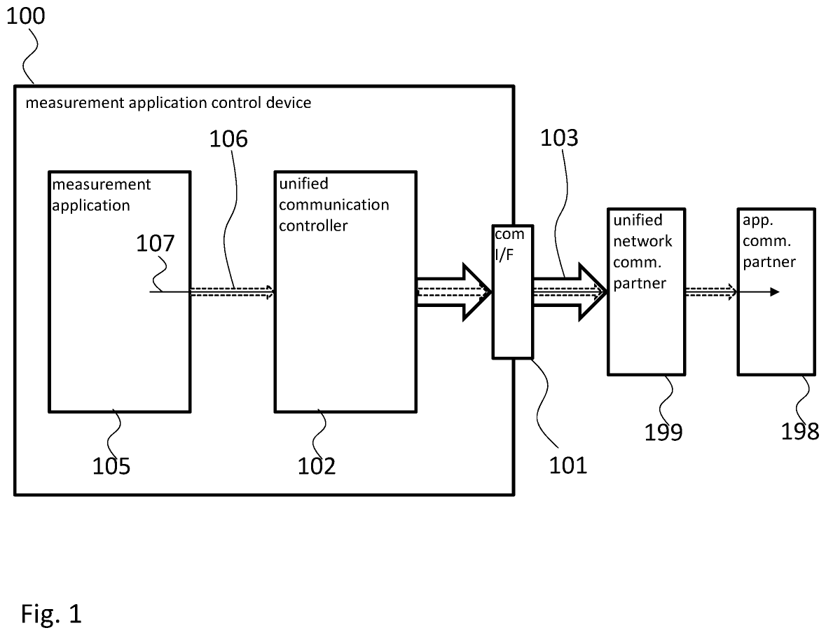

FIG. 1 shows a measurement application control device 100. The measurement application control device 100 comprises a unified communication controller 102 that is coupled to a communication interface 101, and to a measurement application 105.

The unified communication controller 102 establishes a communication connection 103 to a unified network communication partner 199 via the communication interface 101. Although only one communication connection 103 is shown, the unified communication controller 102 may establish more than one communication connection 103 to the same unified network communication partner 199 or to different unified network communication partners 199.

The measurement application 105 establishes an application data connection 106 to an application communication partner 198 via the unified communication controller 102. When establishing the application data connection 106, the measurement application 105 uses a specific communication pattern of a list of possible communication patterns that are supported by the unified communication controller 102.

The unified communication controller 102 receives the measurement application data 107 of the application data connection 106, and encloses the application data connection 106 in the communication connection 103 for transmission via the communication interface 101. The measurement application data 107 is then transmitted within the application data connection 106, and the communication connection 103 to the unified network communication partner 199. There, the application data connection 106 is unpacked or extracted from the communication connection 103, and finally the application data connection 106 with the measurement application data 107 is provided to the application communication partner 198.

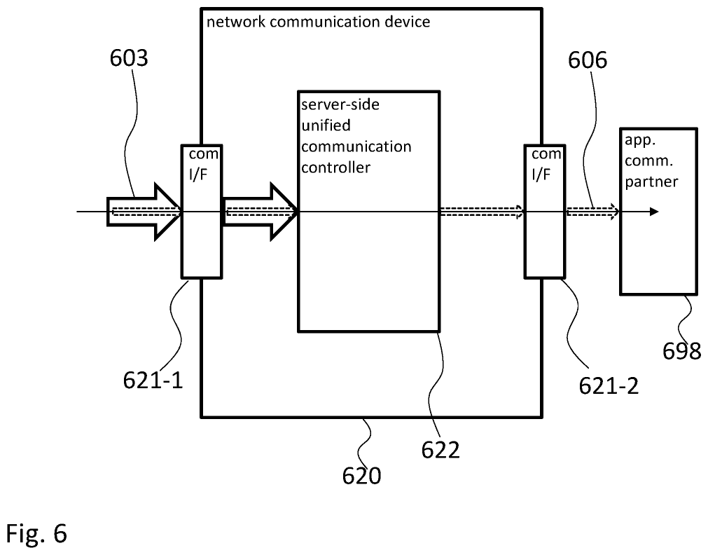

The function of a network communication device as unified network communication partner 199 will be described in more detail with regard to FIG. 6.

The measurement application 105 of the measurement application control device 100 may be a purely software-based application that may comprise a computer program product with computer-readable instructions. When executed, the computer-readable instructions may cause a processor of the measurement application control device 100 to perform the functions described for the measurement application 105. The measurement application 105 may also be provided as a combination of software and hardware. The same applies to the unified communication controller 102.

In exemplary embodiments, the measurement application 105 may comprise a monitoring and remote-control application for monitoring and controlling one or more measurement application devices that may form the unified network communication partner(s) 199. Such a remote-control application may display UI elements on a screen of the measurement application control device 100 that may serve for a user to control the measurement application devices by manipulating the respective UI elements. Each one of the UI elements may establish a dedicated application data connection 106, while all the application data connections 106 may be enclosed in one communication connection 103.

The remote-control application may be provided purely in software e.g., as a web site that is delivered by a server e.g., the unified network communication partner 199, to a computing device of a user e.g., a computer, or tablet PC, or smartphone. The unified communication controller 102 may in such embodiments be provided e.g., as JavaScript library.

In other embodiments, the remote-control application may be provided as application that runs on a measurement application device. This measurement application device in such an embodiment serves as measurement application control device 100. The remote-control application may in such embodiments also comprise or access hardware input elements of the respective measurement application device. Switches or buttons of the measurement application device may e.g., be used by the remote-control application to receive user input. This user input may then be re-routed to the remote-control application instead of the internal control system of the measurement application device. Such a remote-control application may be provided as native application e.g., a C++ application, that is executed on a processor of the measurement application device. The unified communication controller 102 may in such embodiments be provided e.g., as dynamically loadable library like a C++ library.

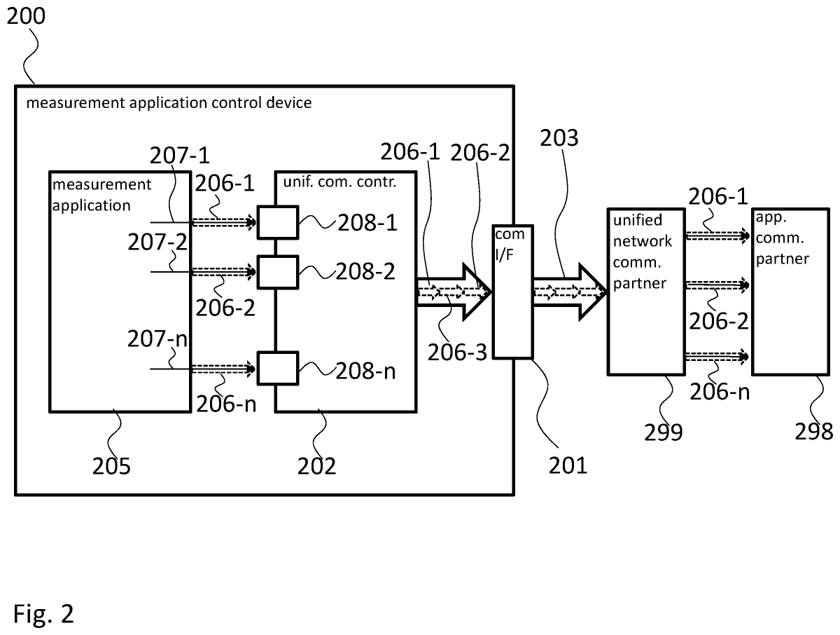

FIG. 2 shows a measurement application control device 200. The measurement application control device 200 is based on the measurement application control device 100. Therefore, the measurement application control device 200 comprises a unified communication controller 202 that is coupled to a communication interface 201, and to a measurement application 205.

The unified communication controller 202 establishes a communication connection 203 to a unified network communication partner 299. Although only one communication connection 203 is shown, the unified communication controller 202 may establish more than one communication connection 203 to the same unified network communication partner 299 or to different unified network communication partners 299.

The explanations provided above, regarding the measurement application control device 100 apply mutatis mutandis to the measurement application control device 200. Further, the features of measurement application control device 200 may be combined with the features of any other embodiment of the measurement application control device disclosed herein.

In the measurement application control device 200, in contrast to the measurement application control device 100, the unified communication controller 202 comprises a number of pattern-specific interfaces 208-1, 208-2, 208-n. While three pattern-specific interfaces 208-1, 208-2, 208-n are shown, any number of pattern-specific interfaces 208-1, 208-2, 208-n is possible in the unified communication controller 202. Each one of the pattern-specific interfaces 208-1, 208-2, 208-n is adapted to a specific communication pattern, like the request-response pattern, the publish-subscribe pattern, or any other communication pattern. In embodiments, one pattern-specific interface 208-1, 208-2, 208-n may be provided for each possible communication pattern. Each one of the pattern-specific interfaces 208-1, 208-2, 208-n may be adapted to establish multiple application data connections 206-1, 206-2, 206-n. In other embodiments, multiple pattern-specific interfaces 208-1, 208-2, 208-n may be provided for each possible communication pattern.

The measurement application 205 establishes multiple application data connections 206-1, 206-2, 206-n. The number of three application data connections 206-1, 206-2, 206-n is just exemplarily chosen, and any other number of application data connections 206-1, 206-2, 206-n is possible.

The unified communication controller 202 encloses the application data connections 206-1, 206-2, 206-n into a single communication connection 203 and provides the respective measurement application data 207-1, 207-2, 207-n in the application data connections 206-1, 206-2, 206-n to the unified network communication partner 299.

The unified network communication partner 299 unpacks all application data connections 206-1, 206-2, 206-n and forwards them and the measurement application data 207-1, 207-2, 207-n to the application communication partner 298.

In embodiments, the single application data connections 206-1, 206-2, 206-n may be destined for different application communication partners 298. The unified network communication partner 299 will then forward the single application data connections 206-1, 206-2, 206-n to the respective receivers.

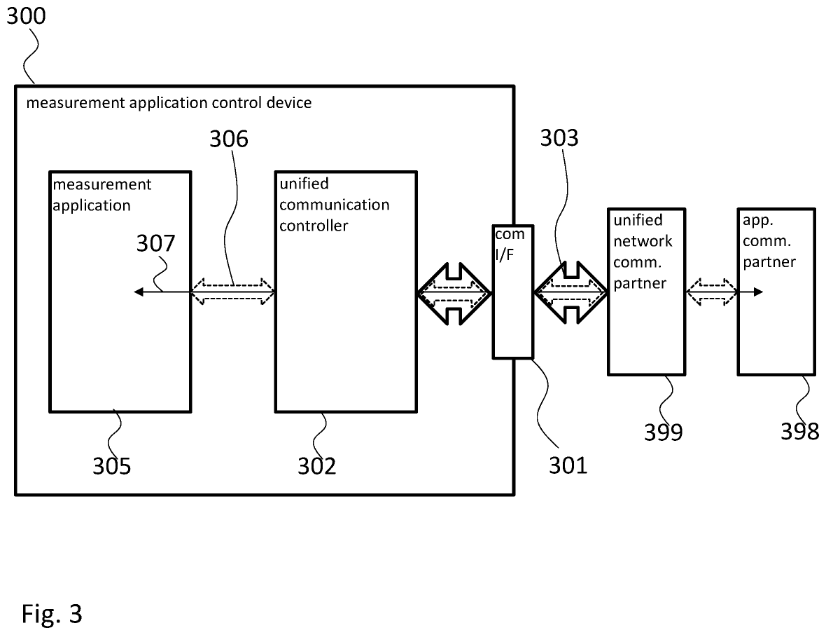

FIG. 3 shows a measurement application control device 300. The measurement application control device 300 is based on the measurement application control device 100. Therefore, the measurement application control device 300 comprises a unified communication controller 302 that is coupled to a communication interface 301, and to a measurement application 305.

The unified communication controller 302 establishes a communication connection 303 to a unified network communication partner 399. Although only one communication connection 303 is shown, the unified communication controller 302 may establish more than one communication connection 303 to the same unified network communication partner 399 or to different unified network communication partners 399.

The explanations provided above, regarding the measurement application control device 100 apply mutatis mutandis to the measurement application control device 300. Further, the features of measurement application control device 300 may be combined with the features of any other embodiment of the measurement application control device disclosed herein.

In the measurement application control device 300, the communication connection 303 and the application data connection 306 are bi-directional connections, and allow the measurement application 305 to receive data from the application communication partner 398.

Providing a bi-directional application data connection 306 between the measurement application 305, and the application communication partner 398, allows providing feedback or measurement application data to the measurement application 305 e.g., for displaying to the user.

In such embodiments, not only control of a measurement application device is possible, but also the displaying of e.g., measurement data like waveforms, on a display of the measurement application control device 300 is possible.

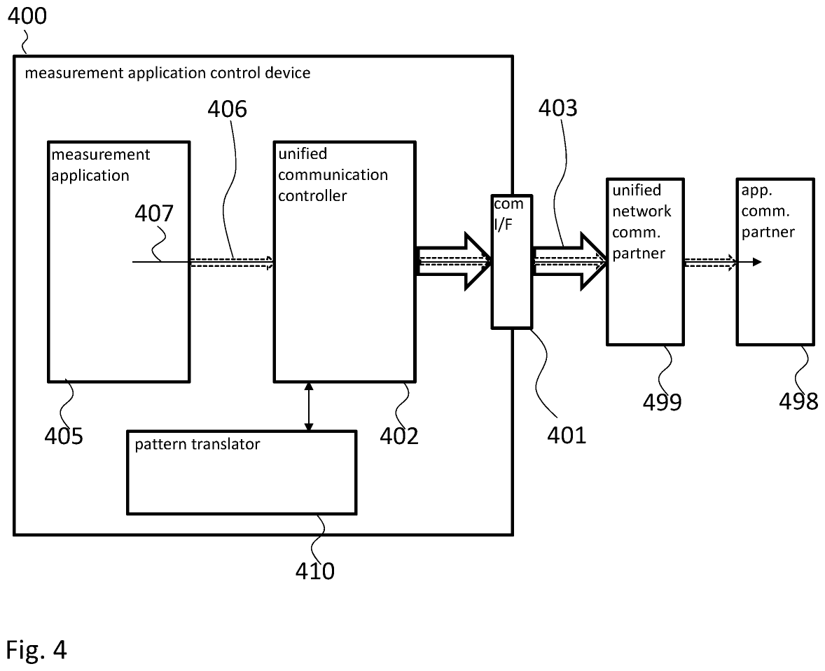

FIG. 4 shows a measurement application control device 400. The measurement application control device 400 is based on the measurement application control device 100. Therefore, the measurement application control device 400 comprises a unified communication controller 402 that is coupled to a communication interface 401, and to a measurement application 405.

The unified communication controller 402 establishes a communication connection 403 to a unified network communication partner 499. Although only one communication connection 403 is shown, the unified communication controller 402 may establish more than one communication connection 403 to the same unified network communication partner 499 or to different unified network communication partners 499.

The explanations provided above, regarding the measurement application control device 100 apply mutatis mutandis to the measurement application control device 400. Further, the features of measurement application control device 400 may be combined with the features of any other embodiment of the measurement application control device disclosed herein.

The measurement application control device 400 further comprises a pattern translator 410 that is coupled to the unified communication controller 402. The unified communication controller 402 may be used by the unified communication controller 402 to translate data according to a predetermined communication pattern into data according to another communication pattern prior to transmission of the data in the at least one communication connection.

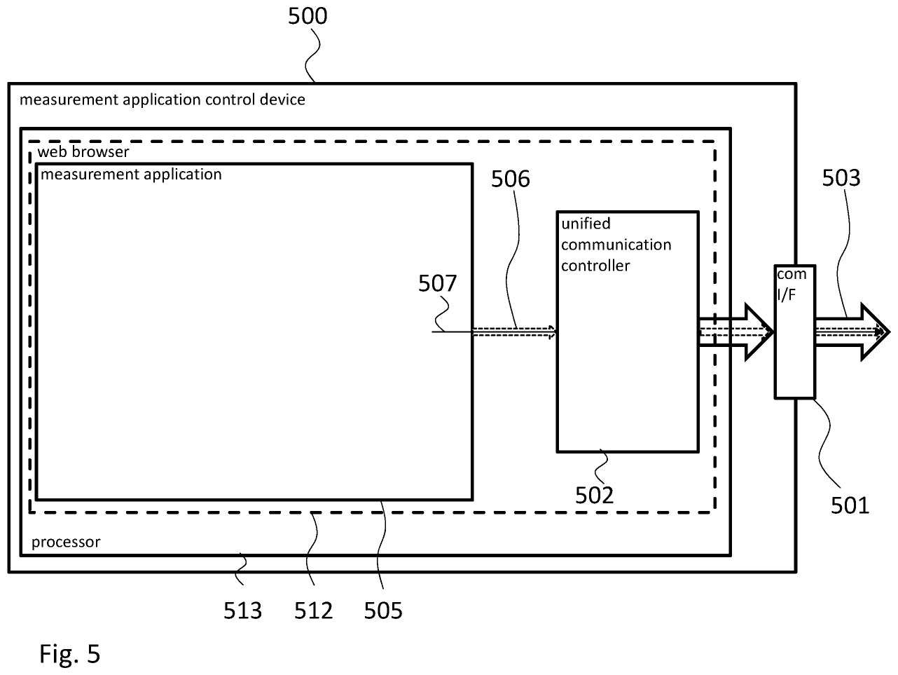

FIG. 5 shows a measurement application control device 500. The measurement application control device 500 is based on the measurement application control device 100. Therefore, the measurement application control device 500 comprises a unified communication controller 502 that is coupled to a communication interface 501, and to a measurement application 505.

The unified communication controller 502 establishes a communication connection 503 to a unified network communication partner (not explicitly shown in FIG. 5). Although only one communication connection 503 is shown, the unified communication controller 502 may establish more than one communication connection 503 to the same unified network communication partner or to different unified network communication partners.

The explanations provided above, regarding the measurement application control device 100 apply mutatis mutandis to the measurement application control device 500. Further, the features of measurement application control device 500 may be combined with the features of any other embodiment of the measurement application control device disclosed herein.

The measurement application control device 500 comprises a processor 513 that executes a web browser application 512. The web browser application 512 shows the measurement application 505 in the form of a web page or web site that may be loaded e.g., from a unified network communication partner. Of course, the measurement application 505 may be shown on a display of the measurement application control device 500.

In the embodiment of measurement application control device 500, the unified communication controller 502 may be provided as JavaScript library that is loaded with the web site of the measurement application control device 500. Such a JavaScript library may provide new interfaces or overwrite existing standard interfaces for establishing the one or more application data connections 506.

FIG. 6 shows a network communication device 620 that may serve as application communication partner to any embodiment of the measurement application control device according to the present disclosure.

The network communication device 620 comprises a first communication interface 621-1 that is coupled to a server-side unified communication controller 622. The server-side unified communication controller 622 is also coupled to a second communication interface 621-2.

The server-side unified communication controller 622 establishes at least one communication connection 603 with a measurement application control device (not explicitly shown), and receives data of at least one application data connection 606 through the communication connection 603. The server-side unified communication controller 622 unpacks or extracts the single application data connections 606 from the communication connection 603 and provides the application data connections 606 to the application communication partner 698 through the second communication interface 621-2.

The server-side unified communication controller 622 may be seen as the counterpart to the unified communication controller in the measurement application control device, and may be implement in any manner, as also described for unified communication controller in the measurement application control device.

The server-side unified communication controller 622 may e.g., be provided as JavaScript library in a respective npm package for usage in a Node-based server environment. Of course, the server-side unified communication controller 622 may also be provided as a traditional application with respective network connections, or as server component that is executed within a web-server environment.

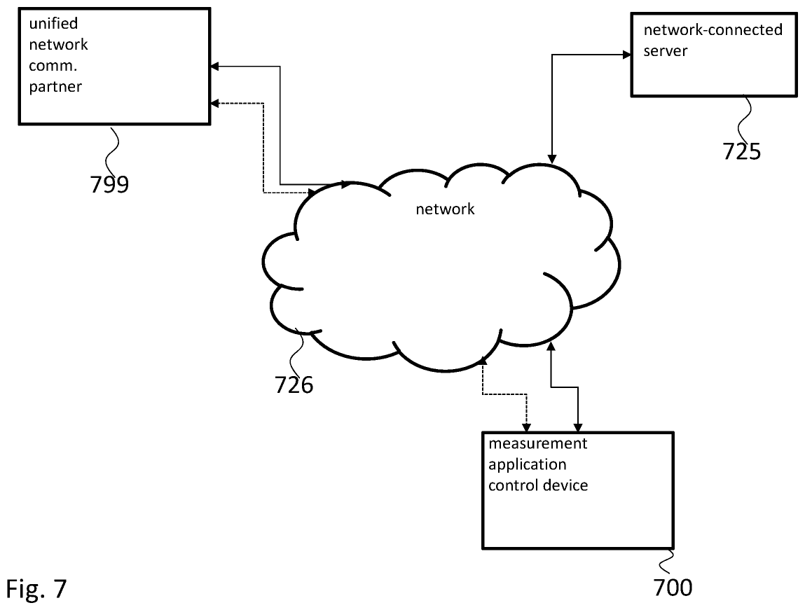

FIG. 7 shows a measurement application with a measurement application control device 700 that is coupled to a network 726. Further, a network-connected server 725 is coupled to the network 726, and a unified network communication partner 799 is coupled to the network 726.

In the measurement application, the unified network communication partner 799 may comprise the application communication partner, or the network-connected server 725 may comprise the application communication partner. If the application communication partner is provided in the network-connected server 725, the communication between the measurement application control device 700, and the unified network communication partner 799 may be performed indirectly via the network-connected server 725.

With the application communication partner in the unified network communication partner 799, the unified communication controller in the measurement application control device 700 may retrieve communication details, like a TCP/IP address and a port number, for the unified network communication partner 799 from the network-connected server 725. The connection, shown as dotted lines, may then be established directly between the measurement application control device 700, and the unified network communication partner 799.

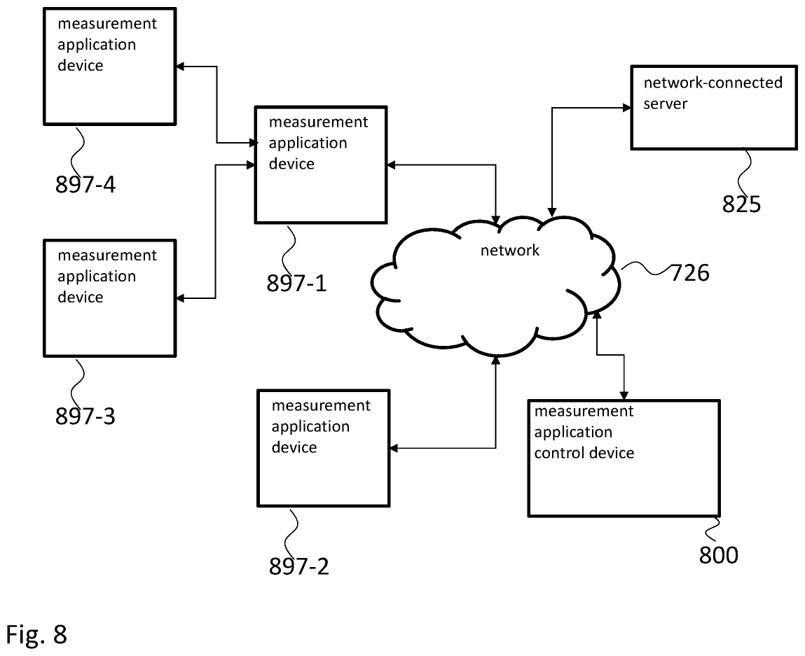

FIG. 8 shows a measurement application with a measurement application control device 800 that is coupled to a network 826, and a network-connected server 825 that is also coupled to the network 826, and with four exemplary measurement application devices 897-1, 897-2, 897-3, 897-4.

In the measurement application of FIG. 8, the communication between the measurement application control device 800, and the measurement application devices 897-1, 897-2, 897-3, 897-4 may be directly or indirectly, as described for FIG. 7. The measurement application devices 897-1, 897-2, 897-3, 897-4 may, therefore, comprise the unified network communication partner and implement the application communication partner.

As an exemplary embodiment, the measurement application device 897-1 may further operate as bridge for the measurement application devices 897-3, 897-4. The measurement application device 897-1 may, therefore, comprise the functionality of a bridge or router. In embodiments, the measurement application device 897-1 may e.g., be coupled to the measurement application devices 897-3, 897-4 in a secure environment and be the gateway for the communication to the measurement application devices 897-3, 897-4.

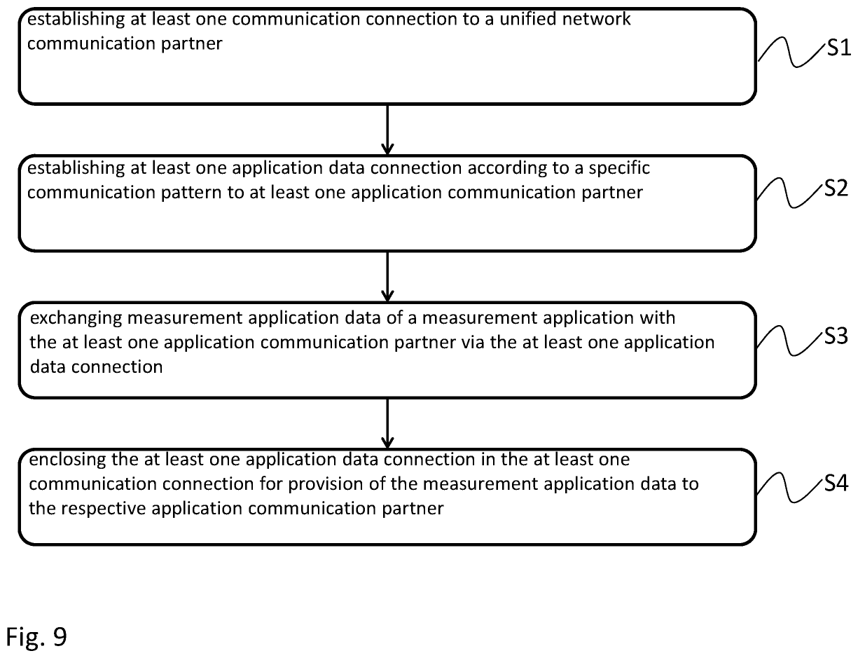

FIG. 9 shows a flow diagram of a measurement application control method. The method comprises establishing S1 at least one communication connection to a unified network communication partner, establishing S2 at least one application data connection according to a specific communication pattern to at least one application communication partner, exchanging S3 measurement application data of a measurement application with the at least one application communication partner via the at least one application data connection, and enclosing S4 the at least one application data connection in the at least one communication connection for provision of the measurement application data to the respective application communication partner.

In embodiments, the communication pattern may comprise at least one of a request-response communication pattern, a remote procedure call communication pattern, a publish-subscribe communication pattern, and an event-channel communication pattern. The at least one communication connection may in embodiments comprise at least one of a network connection, a TCP/IP connection, a WebSocket connection, a shared memory connection, and an API function call.

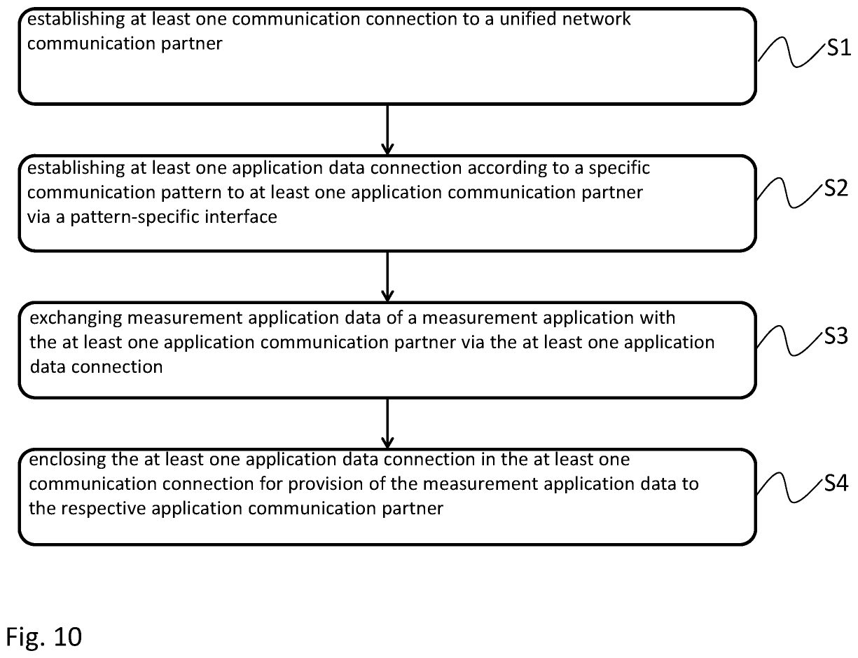

FIG. 10 shows a flow diagram of another measurement application control method that is based on the method shown in FIG. 9. The explanations regarding the method of FIG. 9 apply to the method of FIG. 10 mutatis mutandis.

In the method of FIG. 10, in the step of establishing S2 at least one application data connection according to a specific communication pattern, the at least one application data connection is established via a respective pattern-specific interface. Such a pattern-specific interface may be provided by a unified communication controller.

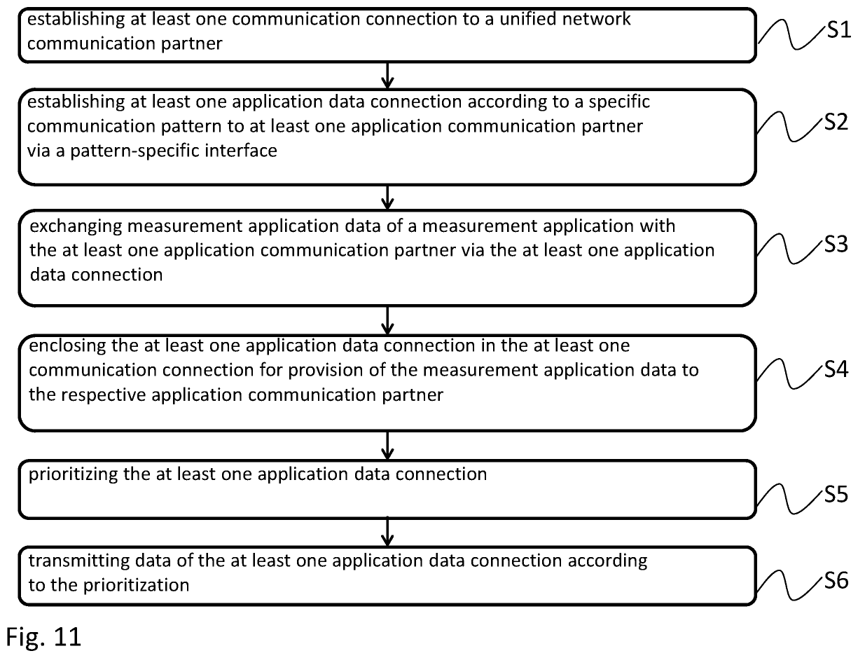

FIG. 11 shows a flow diagram of another measurement application control method that is based on the method shown in FIG. 9. The explanations regarding the method of FIG. 9 apply to the method of FIG. 11 mutatis mutandis.

The method of FIG. 11 further comprises the steps of prioritizing S5 the application data connections, and transmitting S6 data of the at least one application data connection according to the prioritization.

It is understood, that prioritizing S5, and transmitting S6, while shown after step S4, may be performed after any other steps, if adequate.

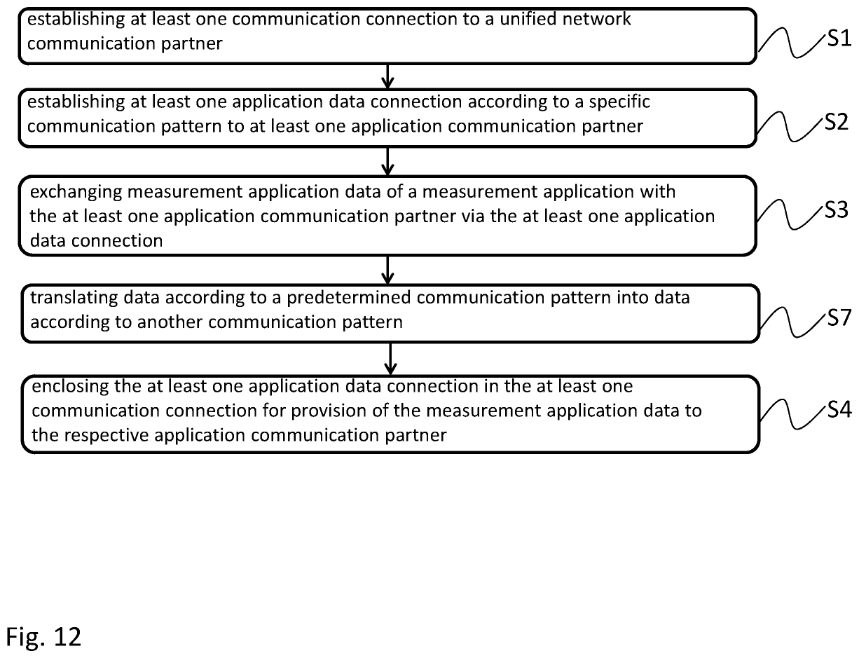

FIG. 12 shows a flow diagram of another measurement application control method that is based on the method shown in FIG. 9. The explanations regarding the method of FIG. 9 apply to the method of FIG. 12 mutatis mutandis.

The method of FIG. 12 further comprises the step of translating S7 data according to a predetermined communication pattern into data according to another communication pattern. This translation allows easily adapting the communication between a measurement application and the respective application communication partner if both use different communication patterns.

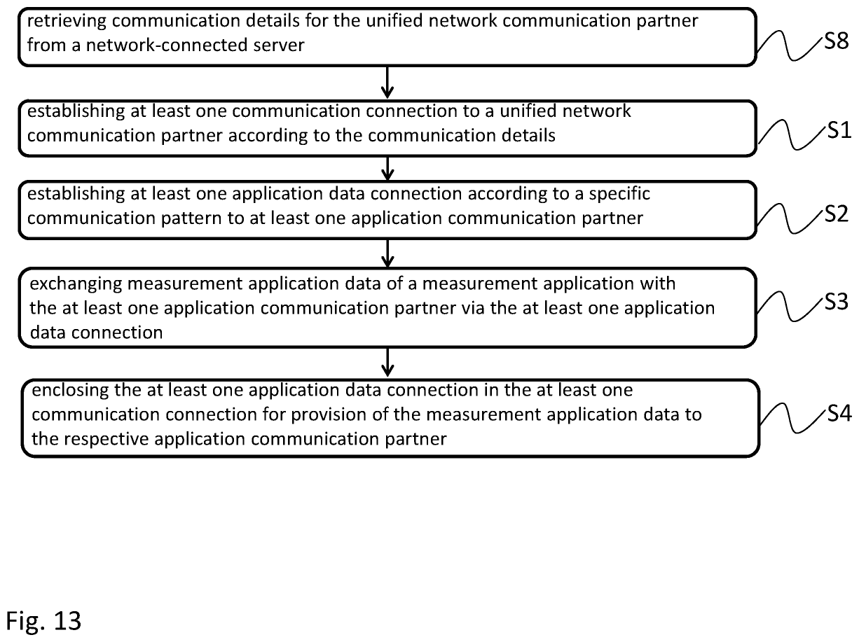

FIG. 13 shows a flow diagram of another measurement application control method that is based on the method shown in FIG. 9. The explanations regarding the method of FIG. 9 apply to the method of FIG. 13 mutatis mutandis.

The method of FIG. 13 further comprises the step of retrieving S8 communication details for the unified network communication partner from a network-connected server. The communication connection is then established S1 to the unified network communication partner according to the communication details.

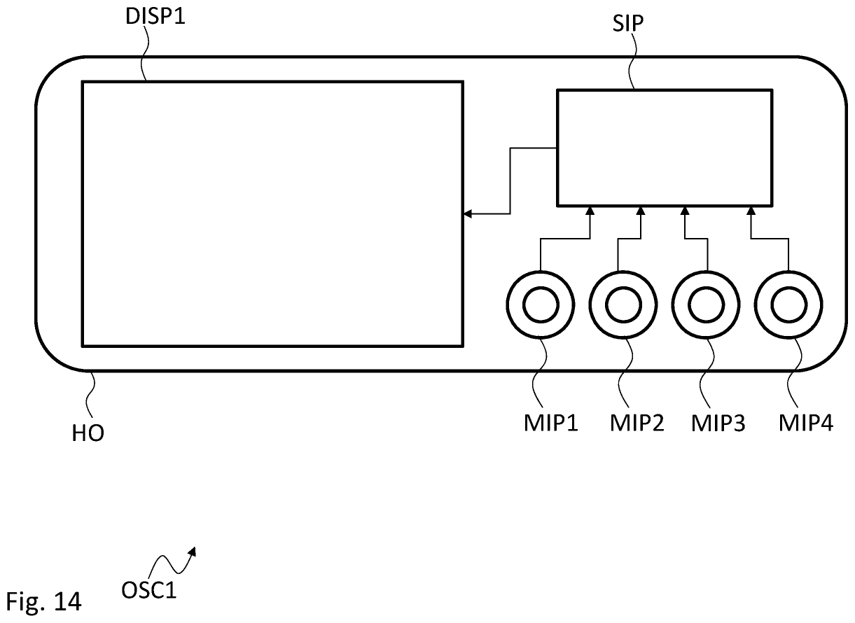

FIG. 14 shows a block diagram of an oscilloscope OSC1 that may be used with an embodiment of a measurement application control device according to the present disclosure.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

Although not explicitly shown, it is understood, that the oscilloscope OSC1 may also comprise signal outputs that may also be coupled to the differential measurement probe. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSC1 the signal processor SIP or an additional processing element may perform the function of the processor of the measurement application control device according to the present disclosure, or may implement the unified communication controller. Of course, a communication interface may be provided in the oscilloscope OSC1 for communication with other measurement application devices, or an external measurement application control device.

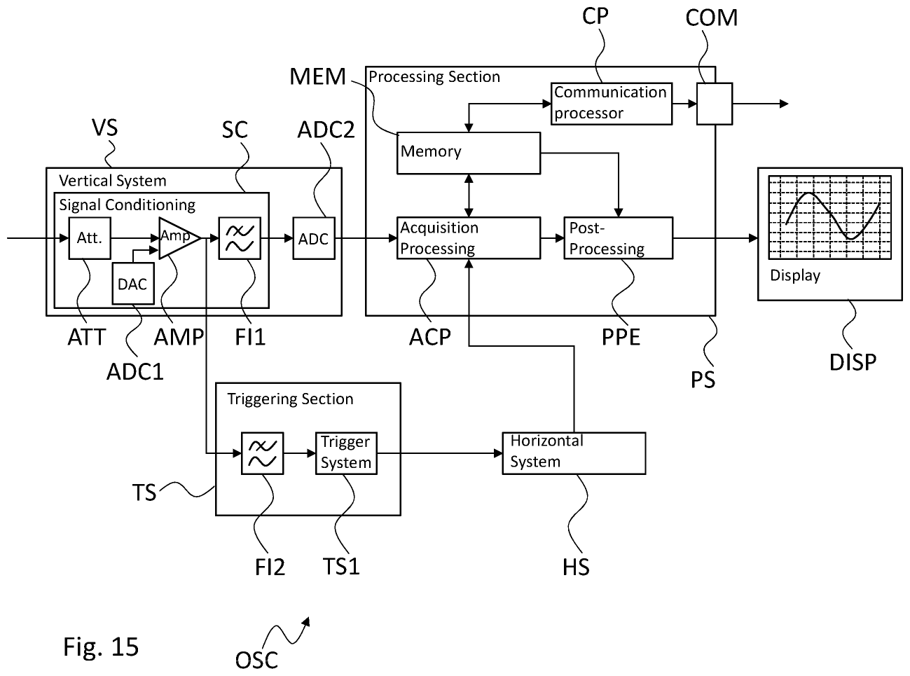

FIG. 15 shows a block diagram of an oscilloscope OSC that may comprise an implementation of a measurement application control device according to the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS, and the display DISP. It is understood, that the partitioning into five general sections is a logical partitioning and does not limit the placement and implementation of any of the elements of the oscilloscope OSC in any way.

The vertical system VS mainly serves for offsetting, attenuating, and amplifying a signal to be acquired. The signal may for example be modified to fit in the available space on the display DISP or to comprise a vertical size as configured by a user.

To this end, the vertical system VS comprises a signal conditioning section SC with an attenuator ATT and a digital-to-analog-converter DAC that are coupled to an amplifier AMP1. The amplifier AMP1 is coupled to a filter FI1, which in the shown example is provided as a low pass filter. The vertical system VS also comprises an analog-to-digital converter ADC1 that receives the output from the filter FI1 and converts the received analog signal into a digital signal.

The attenuator ATT and the amplifier AMP1 serve to scale the amplitude of the signal to be acquired to match the operation range of the analog-to-digital converter ADC1. The digital-to-analog-converter DAC1 serves to modify the DC component of the input signal to be acquired to match the operation range of the analog-to-digital converter ADC1. The filter FI1 serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC1 and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC1.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC1 and the output of the horizontal system HS as well as to a memory MEM and a post processing element PPE.

The acquisition processing element ACP manages the acquisition of digital data from the analog-to-digital converter ADC1 and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

In the oscilloscope OSC, any one of the processing elements in the processing section PS or an additional processing element may perform the function of the processor of the measurement application control device according to the present disclosure, or may implement the unified communication controller.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software, and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100, 200, 300, 400, 500, 700, 800 measurement application control device
101, 201, 301, 401, 501 communication interface
102, 202, 302, 402, 502 unified communication controller
103, 203, 303, 403, 503, 603 communication connection
105, 205, 305, 405, 505 measurement application
106, 206-1, 206-2, 206-n, 306, 406, 506 application data connection
606 application data connection
107, 207-1, 207-2, 207-n, 307, 407, 507 measurement application data
208-1, 208-2, 208-n pattern-specific interface
410 pattern translator
512 web browser
513 processor
620 network communication device
621-1, 621-2 communication interface
622 server-side unified communication controller
725, 825 network-connected server
726, 826 network
199, 299, 399, 499, 799 unified network communication partner
198, 298, 398, 498, 698 application communication partner
897-1, 897-2, 897-3, 897-4 measurement application device
S1-S8 method steps
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
DAC1 analog-to-digital converter
AMP1 amplifier
FI1 filter
ADC1 analog-to-digital converter
TS triggering section
AMP2 amplifier
FI2 filter
TS1 trigger system
HS horizontal system
PS processing section
ACP acquisition processing element
MEM memory
PPE post processing element
DISP display

1. A measurement application control device comprising:
a communication interface; and
a processor configured to execute instructions that cause the processor to perform the functions of:
a unified communication library configured to establish at least one communication connection to a unified network communication partner over the communication interface; and
a measurement application configured to establish at least one application data connection according to a specific communication pattern to at least one application communication partner via the unified communication library, and to exchange measurement application data with the at least one application communication partner via the at least one application data connection,
wherein the unified communication library is further configured to enclose the at least one application data connection in the at least one communication connection for provision of the measurement application data to the respective application communication partner by the unified network communication partner,
wherein the unified communication library comprises a pattern-specific interface for at least one communication pattern, the at least one communication pattern comprising the specific communication pattern, and
wherein the measurement application is configured to establish the at least one application data connection via the pattern-specific interface.

2. The measurement application control device according to claim 1, wherein the specific communication pattern comprises at least one of:
a request-response communication pattern;
a publish-subscribe communication pattern;
a remote procedure call communication pattern; or
an event-channel communication pattern.

3. The measurement application control device according to claim 1, wherein the at least one communication connection comprises at least one of:
a network connection;
a Transmission Control Protocol/Internet Protocol (TCP/IP) connection;
a WebSocket connection;
a shared memory connection; or
an Application Programming Interface (API) function call.

4. The measurement application control device according to claim 1, wherein the unified communication library is configured to prioritize the at least one application data connection, and transmit data of the at least one application data connection according to the prioritization.

5. The measurement application control device according to claim 1, wherein the unified communication library is configured to receive data for the at least one application data connection via the at least one communication connection, and forward the data to the measurement application.

6. The measurement application control device according to claim 1, further comprising a pattern translator library configured to translate data according to a predetermined communication pattern into data according to another communication pattern;
wherein the unified communication library is configured to access the pattern translator library to translate data according to the predetermined communication pattern into data according to the other communication pattern prior to transmission of the data in the at least one communication connection.

7. The measurement application control device according to claim 1, wherein the unified communication library is configured to retrieve communication details for the unified network communication partner from a network-connected server, and to establish the communication connection to the unified network communication partner according to the communication details;
wherein the communication details comprise at least a TCP/IP network address and a TCP/IP port.

8. A measurement application control device comprising:
a communication interface;
a unified communication controller configured to establish at least one communication connection to a unified network communication partner over the communication interface; and
a measurement application configured to establish at least one application data connection according to a specific communication pattern to at least one application communication partner via the unified communication controller, and to exchange measurement application data with the at least one application communication partner via the at least one application data connection,
wherein the unified communication controller is configured to enclose the at least one application data connection in the at least one communication connection for provision of the measurement application data to the respective application communication partner by the unified network communication partner.

9. The measurement application control device according to claim 8, wherein the unified communication controller comprises a pattern-specific interface for at least one communication pattern; and
wherein the measurement application is configured to establish the at least one application data connection via the pattern-specific interface.

10. The measurement application control device according to claim 8, wherein the communication pattern comprises at least one of:
a request-response communication pattern;
a remote procedure call communication pattern;
a publish-subscribe communication pattern; or
an event-channel communication pattern.

11. The measurement application control device according to claim 8, wherein the at least one communication connection comprises at least one of:
a network connection;
a TCP/IP connection
a WebSocket connection;
a shared memory connection; or
an API function call.

12. The measurement application control device according to claim 8, wherein the unified communication controller is configured to prioritize the at least one application data connection, and transmit data of the at least one application data connection according to the prioritization.

13. The measurement application control device according to claim 8, wherein the unified communication controller is configured to receive data for the at least one application data connection via the at least one communication connection, and forward the data to the measurement application.

14. The measurement application control device according to claim 8, further comprising a pattern translator configured to translate data according to a predetermined communication pattern into data according to another communication pattern;
wherein the unified communication controller is configured to access the pattern translator to translate data according to the predetermined communication pattern into data according to the other communication pattern prior to transmission of the data in the at least one communication connection.

15. The measurement application control device according to claim 8, wherein the unified communication controller is configured to retrieve communication details for the unified network communication partner from a network-connected server, and to establish the communication connection to the unified network communication partner according to the communication details,
wherein the communication details comprise at least a TCP/IP network address and a TCP/IP port.

16. A network communication device comprising:
a communication interface; and
a server-side unified communication controller configured to establish at least one communication connection with a measurement application control device over the communication interface,
wherein the server-side unified communication controller is configured to receive data for at least one application data connection via the at least one communication connection, and to unpack the data, and to forward the data to a respective application communication partner.

17. The network communication device according to claim 16, wherein the server-side unified communication controller is further configured to receive data for the at least one application data connection from the respective application communication partner, and transmit the data of the at least one application data connection enclosed in the at least one communication connection to the measurement application control device.

18. The network communication device according to claim 16, wherein the server-side unified communication controller is configured to provide communication details about the network communication device to the measurement application control device for establishing the communication connection to the network communication device according to the communication details,
wherein the communication details comprise at least a TCP/IP network address and a TCP/IP port.

19. A measurement application control method comprising:
establishing at least one communication connection to a unified network communication partner;
establishing at least one application data connection according to a specific communication pattern to at least one application communication partner;
exchanging measurement application data of a measurement application with the at least one application communication partner via the at least one application data connection; and
enclosing the at least one application data connection in the at least one communication connection for provision of the measurement application data to the respective application communication partner.

20. The measurement application control method according to claim 19, further comprising establishing the at least one application data connection via a pattern-specific interface.

21. The measurement application control method according to claim 19, wherein the communication pattern comprises at least one of:
a request-response communication pattern;
a remote procedure call communication pattern;
a publish-subscribe communication pattern; or
an event-channel communication pattern.

22. The measurement application control method according to claim 19, wherein the at least one communication connection comprises at least one of:
a network connection;
a TCP/IP connection
a WebSocket connection;
a shared memory connection; or
an API function call.

23. The measurement application control method according to claim 19, further comprising prioritizing the at least one application data connection, and transmitting data of the at least one application data connection according to the prioritization.

24. The measurement application control method according to claim 19, further comprising receiving data for the at least one application data connection via the at least one communication connection, and forwarding the data to the measurement application.

25. The measurement application control method according to claim 19, further comprising translating data according to a predetermined communication pattern into data according to another communication pattern,
wherein data according to the predetermined communication pattern is translated into data according to another communication pattern prior to transmission of the data in the at least one communication connection.

26. The measurement application control method according to claim 19, further comprising:
retrieving communication details for the unified network communication partner from a network-connected server; and
establishing the communication connection to the unified network communication partner according to the communication details,
wherein the communication details comprise at least a TCP/IP network address and a TCP/IP port.
